(19) United States
(12) Patent Application Publication
(10) Pub. No.: US 2021/0027998 A1
(43) Pub. Date: Jan. 28, 2021

(54) PULSED DC SPUTTERING SYSTEMS AND METHODS

(71) Applicant: Advanced Energy Industries, Inc., Fort Collins, CO (US)

(72) Inventors: Robert George Andosca, Ph.D., Fort Collins, CO (US); Douglas R. Pelleymounter, Northfield, MN (US); David Christie, Fort Collins, CO (US)

(21) Appl. No.: 16/939,548

(22) Filed: Jul. 27, 2020

Related U.S. Application Data
(60) Provisional application No. 62/878,591, filed on Jul. 25, 2019.

(51) Int. Cl. H01J 37/34; C23C 14/34

(52) U.S. Cl. CPC H01J 37/3405; C23C 14/3485; H01J 37/3467

(57) ABSTRACT

Systems and methods for are disclosed. One method includes providing at least a first electrode, a second electrode, and a third electrode and using each of at least two, separate and different, target materials in connection with the three electrodes to enable sputtering. The method also includes applying a first voltage at the first electrode that alternates between positive and negative relative to the second electrode during each of multiple cycles and applying a second voltage to the third electrode that alternates between positive and negative relative to the second electrode during each of the multiple cycles.

### CLAIM OF PRIORITY UNDER 35 U.S.C. § 119

The present application for patent claims priority to Provisional Application No. 62/878,591 entitled “Pulsed DC Sputtering Systems and Methods” filed Jul. 25, 2019, and assigned to the assignee hereof and hereby expressly incorporated by reference herein.

### BACKGROUND

### Field

The present invention relates generally to sputtering systems, and more specifically to pulsed DC sputtering.

### Background

Sputtering historically includes generating a magnetic field in a vacuum chamber and causing a plasma beam in the chamber to strike a sacrificial target, thereby causing the target to sputter (eject) material, which is then deposited as a thin film layer on a substrate, sometimes after reacting with a process gas. Sputtering sources may employ magnetrons that utilize strong electric and magnetic fields to confine charged plasma particles close to the surface of the target. An anode is generally provided to collect electrons from the plasma to maintain plasma neutrality as ions leave to bombard the target.

The industry has evolved over the years in various attempts to maximize sputtering efficiency, decrease power consumption requirements, minimize the heat load of the system, minimize arcing and/or increase the types of substrates that may be used in the system. In addition, sputtering targets have evolved over the years to include composite materials, such as Indium Tin Oxide (ITO), which is often used to make transparent conductive coatings for displays such as liquid crystal displays (LCD), flat panel displays, plasma displays, and touch panels. These composite target materials may include two or more metals that are used as a target on a magnetron and then sputtered to create a layer of the composite material. But these composite targets can be very expensive, which makes the sputtering process very expensive.

Another issue that persists in the industry is the problem of depositing uniform layers of sputtering materials over nonuniform surfaces such as surfaces with trenches. There therefore remains a need for more cost effective and more conformal deposition of target materials.

### SUMMARY

An aspect of the present disclosure is a method for sputtering that includes providing at least a first electrode, a second electrode, and a third electrode. The method also includes applying a first voltage at the first electrode that alternates between positive and negative relative to the second electrode during each of multiple cycles and applying a second voltage to the third electrode that alternates between positive and negative relative to the second electrode during each of the multiple cycles. The method also includes using each of at least two, separate and different, target materials in connection with the three electrodes to enable sputtering.

In some variations of the method, the first electrode and the third electrode each include a magnetron to form a first magnetron and a third magnetron wherein each of the first magnetron and the third magnetron is coupled to a corresponding one of the two separate and different target materials, and wherein the second electrode includes neither a target nor a magnetron to operate as an anode.

In other variations of the method, each of the three electrodes is a magnetron to form a first magnetron, a second magnetron, and a third magnetron wherein one of the at least two, separate and different, target materials is coupled to the first and third magnetron and another of the at least two, separate and different, target materials is coupled to the second magnetron.

In yet other variations of the method, each of the three electrodes is a magnetron to form a first magnetron, a second magnetron, and a third magnetron and the at least two, separate and different, target materials includes three separate and different target materials, wherein each of the three separate and different target materials is coupled to a corresponding one of the three magnetrons.

Any and all the variations of the method may include employing a ground shield aperture and moving a substrate in any direction to uniformly to deposit the at least two separate and different target materials on the substrate.

According to another aspect, a pulsed sputtering system is disclosed that includes at least three electrodes: a first electrode, a second electrode, and a third electrode. Each of at least two, separate and different, target materials is used in connection with the three electrodes to enable sputtering. The pulsed sputtering system includes a first power source coupled to the first electrode and the second electrode, wherein the first power source is configured to apply a first voltage at the first electrode that alternates between positive and negative relative to the second electrode during each of multiple cycles and a second power source is coupled to the third electrode and the second electrode, the second power source is configured to apply a second voltage to the third electrode that alternates between positive and negative relative to the second electrode during each of the multiple cycles.

### BRIEF DESCRIPTION OF THE DRAWINGS

FIG. 1 depicts an embodiment of a sputtering system comprising two electrodes and two corresponding target materials;

FIG. 2 is a timing diagram depicting exemplary voltages applied to the electrodes of FIG. 1 over time;

FIG. 3 is a diagram depicting a sputtering system comprising three electrodes and two target materials;

FIG. 4 is a diagram a sputtering system comprising three electrodes and three corresponding target materials

FIG. 5A is a timing diagram depicting exemplary voltages that may be applied to the electrodes of FIGS. 3 and 4;

FIG. 5B is a timing diagram depicting other exemplary voltages that may be applied to the electrodes of FIGS. 3 and 4;

FIG. 5C is a timing diagram depicting yet other exemplary voltages that may be applied to the electrodes of FIGS. 3 and 4;

FIG. 5D is a timing diagram depicting a variation of the exemplary voltages in FIG. 5C that may be applied to the electrodes of FIGS. 3 and 4;

FIG. 6 is a diagram depicting a variation and use case of the embodiment depicted in FIG. 1;

FIG. 7 is a diagram depicting a variation and use case of the embodiment depicted in FIG. 3;

FIG. 8 is a diagram depicting another variation and use case of the embodiment depicted in FIG. 4;

FIG. 9 is a diagram depicting exemplary aspects of the power sources and controller described herein;

FIG. 10 is a block diagram illustrating aspects of components that may be implemented in the systems described herein;

FIG. 11 is a depiction of a single target in connection with a moving substrate consistent with methods used in the prior art;

FIG. 12 is a depiction of directional and single-angle results of sputtering with the single target depicted in FIG. 11;

FIG. 13 is a depiction of multiple targets in connection with a moving substrate consistent with methods disclosed herein; and

FIG. 14 is a depiction of dual angle and multi-angle results of sputtering with multiple targets as disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

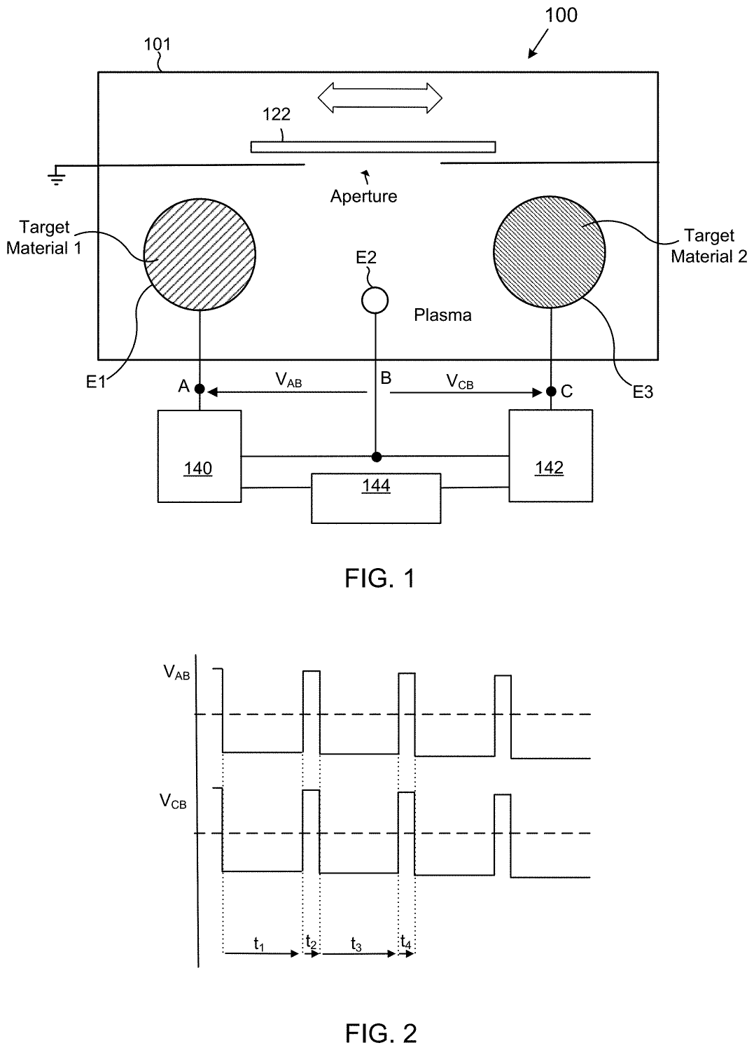

Referring to FIG. 1, an exemplary pulsed, direct current sputtering system 100 is shown. An aspect of the system 100 is the ability to utilize readily available and relatively inexpensive target materials to produce desirable multi-element films with favorable deposition rates as compared to prior AC dual magnetron and pulsed DC single magnetron sputtering approaches. As an example, instead of using a relatively expensive composite target material such as Indium Tin Oxide (ITO), separate less expensive (and readily available) indium and tin based targets (e.g. In and Sn targets, respectfully) targets may be used to achieve a desired ITO film. Another aspect of some variations of the system 100 is the ability to provide conformal, and highly uniform, coatings over varying substrate surface topologies; thus, enabling current and future product designs.

Beneficially, many variations of the system 100 may cut the RMS current in the endblocks or magnetrons by about half as compared to prior AC sputtering systems. As a consequence, in cases in which the endblock current rating is limited, the system 100 may enable delivery of nearly twice the power while staying within the endblock current rating limit. Another aspect of the system depicted in FIG. 1 is that depending upon the type of electrodes that are utilized and the control scheme that is implemented, sputtering occurs at least 70% of the time. And in some implementations, the system 100 is capable of sputtering 80%, 90%, or up to nearly 100% of the time.

Additional aspects of the system 100 include a resultant reduction of heat load to the substrate, or a higher deposition rate at the same substrate heat load. Moreover, another aspect of many implementations is that substantially the same deposition rate (per total power (kW) delivered to the process) can be expected as compared to mid-frequency (MF) (AC or pulsed) dual magnetron sputtering. The system 100 may provide about 2 times the deposition rate of AC dual magnetron or bi-polar pulsed DC sputtering, with lower heat load experienced in typical sputtering systems. As discussed herein, the voltage in each cycle may reverse 100%. And beneficially, some implementations operate while producing undetectable anode material levels in a film on the substrate.

As shown in FIG. 1, the system 100 includes a plasma chamber 101 enclosing at least a first electrode E1, a second electrode E2, and a third electrode E3. The system 100 includes a substrate 122 upon which the system 100 deposits a thin film material in a sputtering process. As shown in FIG. 1, the system 100 includes at least three electrodes, but may include N electrodes where N is greater than three. In some embodiments, six or more electrodes are arranged in groups of three.

In some implementations of FIG. 1, the second electrode E2 is implemented as an anode and the first electrode E1 and the third electrode E3 may each be implemented as a part of a magnetron, but in other implementations the first electrode E1 and the third electrode E3 are not implemented as a part of magnetrons. As shown, a first power source 140 is coupled to the first electrode E1 and the second electrode E2, and the first power source 140 is configured to apply a first voltage VAB at the first electrode E1 that alternates between positive and negative relative to the second electrode E2 during each of multiple cycles. The second power source 142 is coupled to the third electrode E3 and the second electrode E2, and the second power source 142 is configured to apply a second voltage VCB to the third electrode E3 that alternates between positive and negative relative to the anode during each of the multiple cycles.

As shown, a controller 144 is coupled to the first power source 140 and the second power source 142 to control the power sources 140, 142. In some modes of operation, the controller 144 is configured to control the first power source 140 and the second power source 142 to phase-synchronize the first voltage VAB with the second voltage VCB, so both, the first voltage VAB and the second voltage VCB are simultaneously negative during a portion of each cycle and simultaneously positive relative to the anode during another portion of each cycle. In other modes of operation, the controller 144 is configured to control the first power source 140 and the second power source 142 to phase-desynchronize the first voltage VAB with the second voltage VCB, so there is a phase offset between the first voltage VAB and the second voltage VCB. In many variations of the implementation in FIG. 1, the second electrode E2, operating as a shared anode, is cooled (e.g., by water cooling).

As shown, at least two electrodes are each used with a corresponding one of two different target materials (target material 1 and target material 2) so that the system 100 operates in a “co-sputtering” configuration. The materials utilized for target material 1 and target material 2 are different but may vary and may be used in different combinations. For example, the target materials may include, without limitation, aluminum, indium, tin, lead, zirconium, zinc, titanium. Although the target materials may be elemental materials, it is also contemplated that the target materials may include composite materials while each of the two magnetrons is used with a corresponding one of two different composite target materials. Exemplary combinations of target materials include indium coupled to one of the electrodes and tin coupled to the other electrode. Another combination (that may be used in 3-magnetron configurations discussed further herein) is lead, zirconium, titanium.

As described in more detail further herein, a plasma is generated in response to the application of a pulsed voltage within the chamber 101. As those of ordinary skill in the art will appreciate, gases are provided to the plasma chamber 101 and a plasma is ignited within the chamber 101. More specifically, there may be reactant gases and ion peening gases fed into the plasma chamber 101. The reactant gases may include, for example, nitrogen, oxygen, and the ion peening gas may be argon.

As depicted in FIG. 1, and described in more detail further herein, the plasma chamber 101 may also be configured with a horizontal ground shield aperture, and the substrate 122 may be positioned on a platform that is configured to move in any direction to uniformly deposit target material on the substrate.

Referring to FIG. 2, shown is a timing diagram depicting exemplary voltages applied to the electrodes E1 and E3 of FIG. 1 relative to the second electrode E2 (operating as an anode) over time. As shown, at times t1 and t3, electrodes E1 and E3 are sputtering. And at times t2 and t4, the first electrode E1 and third electrode E3 have a positive potential relative to a negative potential of the second electrode E2. As shown, a percentage of time the sputtering is occurring during each cycle (and hence, during the multiple cycles depicted in FIG. 2) is (t1)/(t2), and this percentage in some implementations is at least 70% of the cycle, or in other implementations, the percentage is between 70% and 90% of the cycle. In yet other implementations, the percentage is between 80% and 90% of the cycle, or the percentage may be between 85% and 90% of the cycle. And in yet other implementations, the percentage may be 90% or greater. In other implementations this percentage may be 95% or greater.

To achieve the voltages in FIG. 2, the controller 144 is configured to control the first power source 140 and the second power source 142 to phase-synchronize the first voltage with the second voltage, so both, the first voltage V_{AB} and the second voltage V_{CB}, are simultaneously negative during a portion of each cycle and simultaneously positive relative to the second electrode during another portion of each cycle.

As discussed further herein, each of the first and second power sources 140, 142 may include a bi-polar controllable pulsed DC power supply to apply the first voltage V_{AB} and second voltage V_{CB}. And as discussed in more detail further herein, the controller 144 may be realized by hardware, firmware or a combination of software and hardware and/or hardware and firmware. Moreover, arc management synchronization may be implemented so that a detected arc in the plasma prompts the power sources 140, 142 to stop applying power to the electrodes.

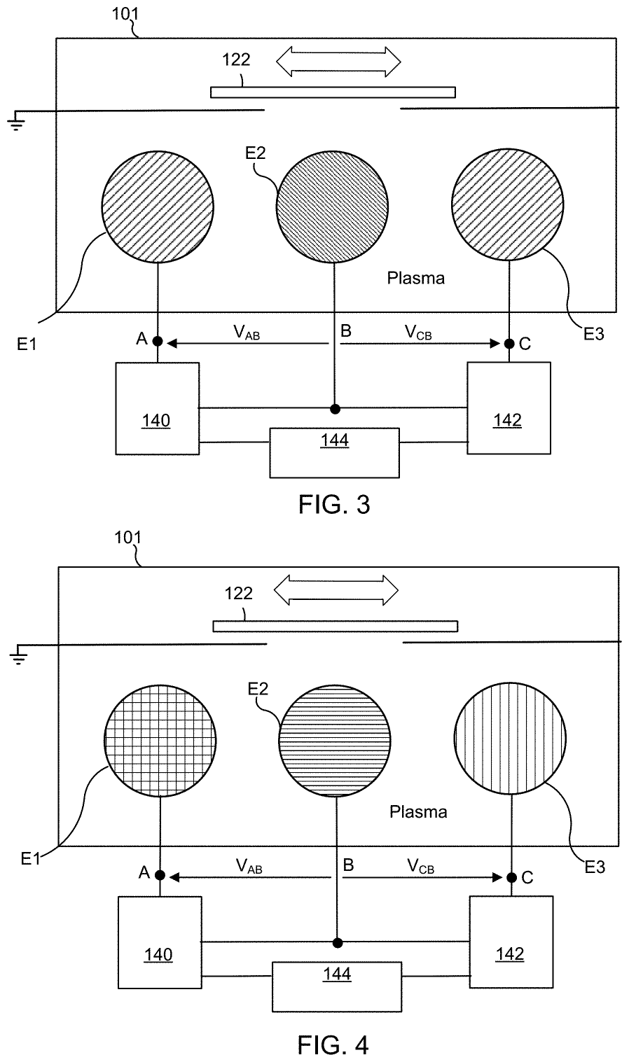

Referring next to FIG. 3, shown is another embodiment in which each of three electrodes is coupled to target material. More specifically, the first electrode E1 and third electrode are coupled to a first target material and the second electrode E2 is coupled to a second target material. FIG. 4 shown is a variation of the system depicted in FIG. 3 in which each of the three electrodes is coupled to a corresponding one of three different target materials.

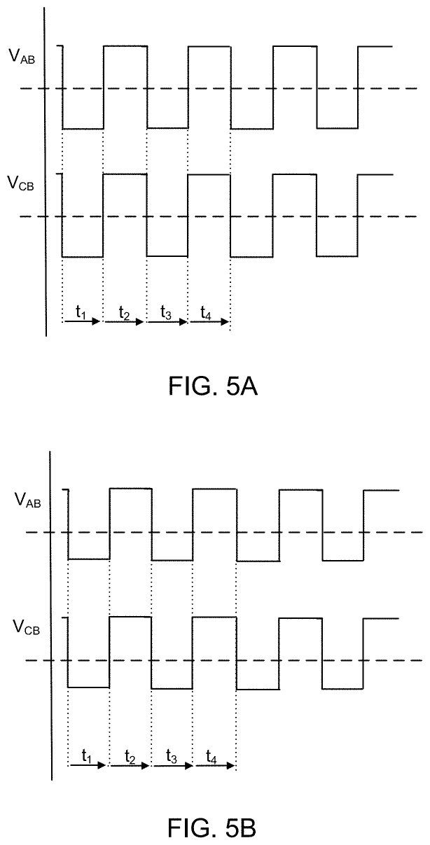

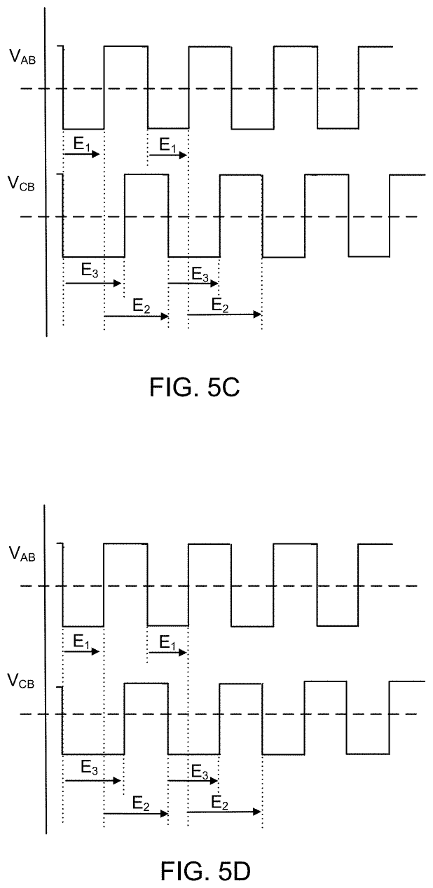

While referring to FIGS. 3 and 4, simultaneous reference is made to FIGS. 5A, 5B, 5C, and 5D, which are timing diagrams depicting exemplary voltages that may be applied to the electrodes of FIGS. 3 and 4 over time. To produce the waveforms in FIG. 5A, the controller 144 is configured to control the first power source 140 and the second power source 142, so both, the first voltage V_{AB} at the first electrode E1 and the second voltage V_{CB} at the third electrode are simultaneously negative relative to the second electrode E2 at least 66 percent of a time over the multiple cycles. As shown, at times t1 and t3 the first and third electrodes E1 and E3 sputter while the second electrode E2 functions as anode, and at times t2 and t4, the second electrode E2 sputters while the first electrode E1 and the third electrode E3 function as anodes. Thus, during one portion of each cycle, ⅔ of the electrodes are sputtering and during the other opposite-polarity-portion of each cycle, ⅓ of the electrodes are sputtering. In other implementations this percentage may be 5-95% for either power source.

Referring to FIG. 5B, there may be a high level (e.g., twice the level) of power for half a cycle (e.g., during time t2) applied to the second electrode E2 than the first electrode E1 and third electrode E3. That is, there will be twice the power at electrode E2 over a period of time. In other words, a magnitude of power is effectively pulsed over time when switching between electrodes (e.g., when switching from time t₁ to t₂).

As shown in FIG. 5C, in some modes of operation, the waveform V_{AB} need not be synchronized with the waveform V_{CB}. Shown in FIG. 5C are exemplary waveforms for V_{AB} and V_{CB} and time periods when the three electrodes E1, E2, and E3 are sputtering. As shown, there are times when electrode E3 sputters simultaneously with electrode E1 and other times when electrode E3 sputters simultaneously with electrode E2.

FIG. 5D depicts a mode of operation where the timing of pulses of the waveforms is the same as FIG. 5C, but an amplitude of a positive portion of the V_{CB} waveform is lower in magnitude than a negative portion of the V_{CB} waveform.

It should be recognized that three electrodes (E1, E2, and E3) are depicted in FIGS. 3 and 4 for simplicity, but it is certainly contemplated that systems may be implemented with more than three electrodes. For example, there may be N electrodes where N is greater than three and N is evenly divisible by 3 so that N/3 groups of electrodes (where each electrode-group includes three electrodes powered by two power sources 140, 142). In these implementations, one electrode-group may include the same target material coupled to each electrode while another electrode-group includes at least two different target materials.

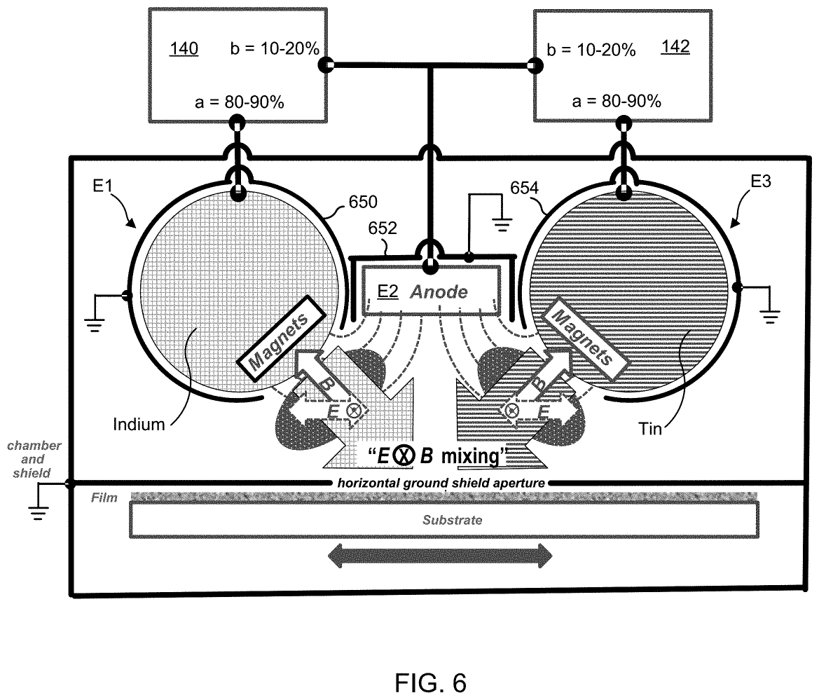

Referring next to FIG. 6, shown is a variation and use case of the system 100 described with reference to FIG. 1 in which the first electrode E1 and the third electrode E3 are each implemented as a part of a corresponding magnetron to form a first magnetron M1 and a third magnetron M3. In the depicted co-sputtering configuration, separate and less expensive indium (In) and tin (Sn) based (e.g. In and Sn, respectfully) targets are used with ground shields. In this variation, the first magnetron M1 is implemented with an optional fixed ground shield 650, the second electrode E2 is implemented with a corresponding optional ground shield 652, and the third magnetron M3 is also implemented with a corresponding optional ground shield 654. In operation, a “dark space” is created in between each magnetron M1, M3 and its shield 650, 654, which also serves to concentrate the directional sputtered neutral In and Sn species. Also shown are magnets that are placed at angles such that the sputtered In and Sn neutral species are directed towards the center, such that they “mix” together. The second electrode E2 is placed in between the magnetrons M1, M3 with the ground shield 652 surrounding the sides and a backside, and a dark space is created in between the second electrode E2 and its shield 652. Because the second electrode E2 is not coupled to target material in this implementation, it may be referred to as an anode, but it should be recognized that the voltage of the electrode E2 does experience a negative portion relative to each of the magnetrons M1 and M2 during each cycle; thus, the second electrode E2 only operates as an anode during a portion of each cycle.

In an exemplary mode of operation, the magnetrons M1, M3 share the same duty, which is referred to in FIG. 6 as the “a” side and the shared second electrode E2 is referred to as the “b” side. The magnetic field B and the alternating electric field E (at pulsing frequency f (a/b) between the magnetrons M1, M3 and common, second electrode E2) act on the positive ions and negative electrons in the oxygen (02)/argon (Ar) plasma. The two force vectors FB (Lorentz force) and FE act on the charged particles as the cross product X and result in lateral alternating motion of the charged particles or “E×B mixing,” which is a resultant force vector FR in and out of the page. This mixing, depending on process pressure (mean-free-path MFP between particles), results in more collisions with In and Sn neutral species, and thus, creates a more stoichiometric ITO film. Higher pressure results in more mixing.

In operation, a power set point may be different for the second power source 142 that directly affects the power applied to the tin target as compared to the first power source 140 that directly affects the power applied to the indium target (to compensate for lower sputtering yield of tin as contrasted with indium), which results in a more stoichiometric ITO film. Using the depicted configuration may yield up to twice the deposition rate of using a standard co-sputtering dual magnetron sputtering configuration. And the yield from the system in FIG. 6 may be higher than using ITO targets because the sputtering yield is lower for a composite ITO target than separate indium and tin targets.

Although not required, a bias voltage can be applied to substrate holder to increase ion peening energy to densify the ITO film while enhancing other material properties at potentially lower substrate temperatures. In addition, the substrate may move back and forth under the horizontal ground shield aperture so the deposited ITO film thickness and materials properties are substantially uniform across the entire substrate.

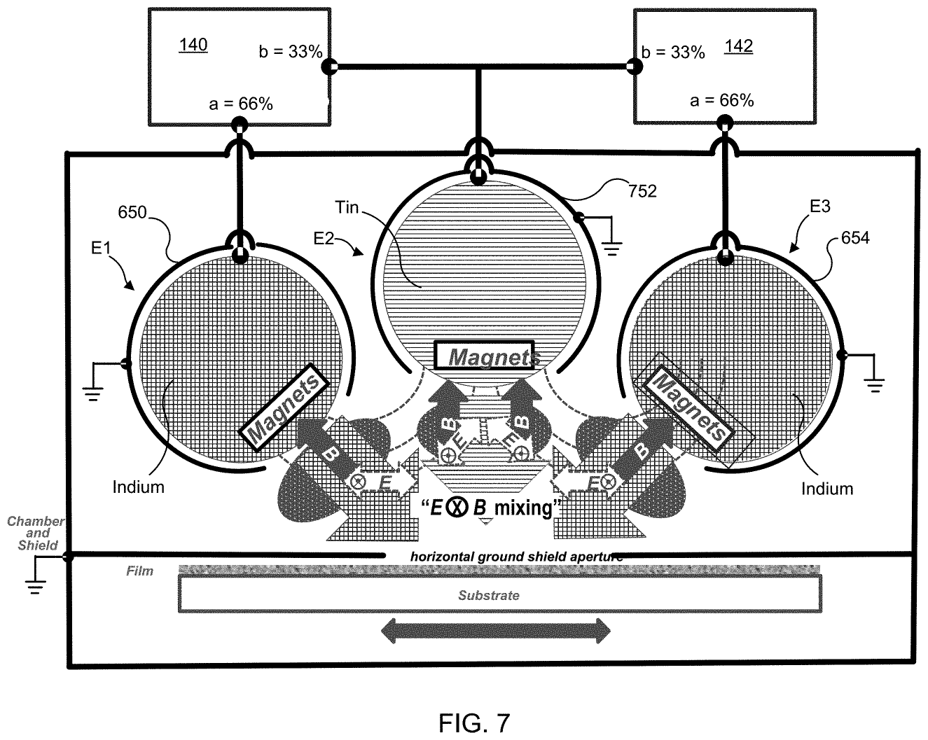

Referring to FIG. 7, shown is a variation and use case of the system described with reference to FIG. 3. As shown, in this variation the second electrode E2 is realized by a second magnetron M2 that is implemented in connection with an optional ground shield 752. In addition, Indium targets are used with the outer magnetrons M1, M3 (on the “a” side), and tin is used with the second magnetron M2 (on the “b” side). In this use case, the duty-cycle of sides “a” may be 66% and side “b” may be 33%, but in other use cases the duty-cycles can certainly vary. The power set points of the power sources 140, 142 can be different based upon the target materials to help control thin film stoichiometry. In an alternative use case, there may be two tin-based based targets coupled to the outer magnetrons M1, M3 and one indium-based target coupled to the second magnetron.

In both use cases depicted in FIGS. 6 and 7, the two constituent elements (indium and tin) may react with oxygen (O) in an O₂/argon (Ar—large inert sputtering ions) plasma to produce In₂O₅Sn (ITO), which is an electrically conductive, optically transparent material that is widely used for flat panel displays, solar cells, touch panels, organic light emitting diodes, and other applications.

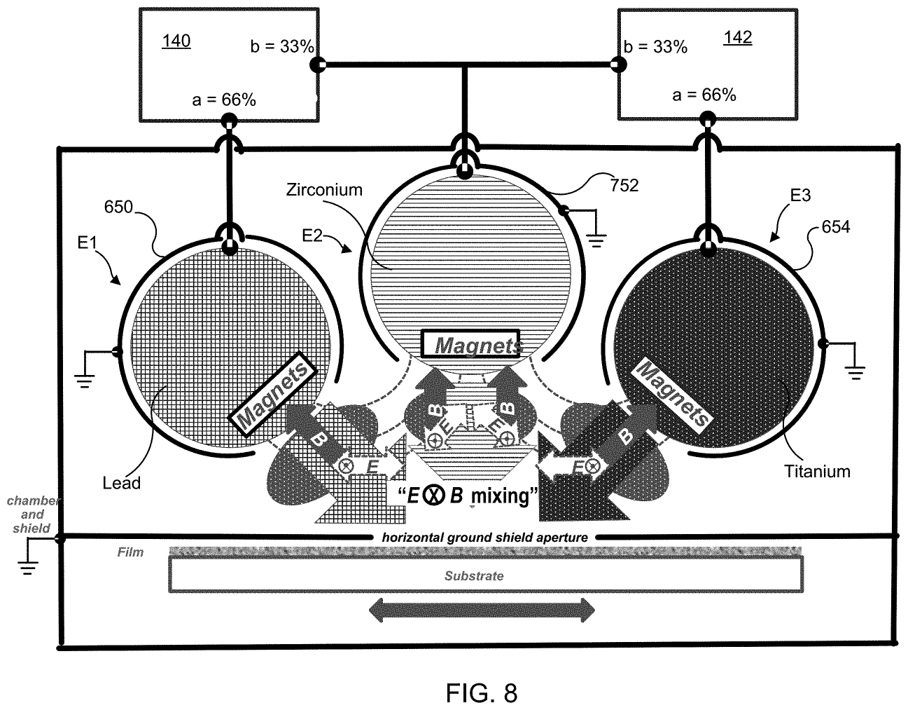

Referring next to FIG. 8, shown is another variation and use case of the system described with reference to FIG. 3 in which each of the three magnetrons M1, M2, M3 is used with a corresponding one of three different target materials: lead, zirconium, and titanium to produce a lead zirconate titanate (PZT) film (Pb[ZrₓTi₁₋ₓ]O₃ (0<x<1)). In operation, the three constituent elements (lead, zirconium, and titanium) react with oxygen (O) in an O₂/argon (Ar—large inert sputtering ions) plasma to produce the PZT.

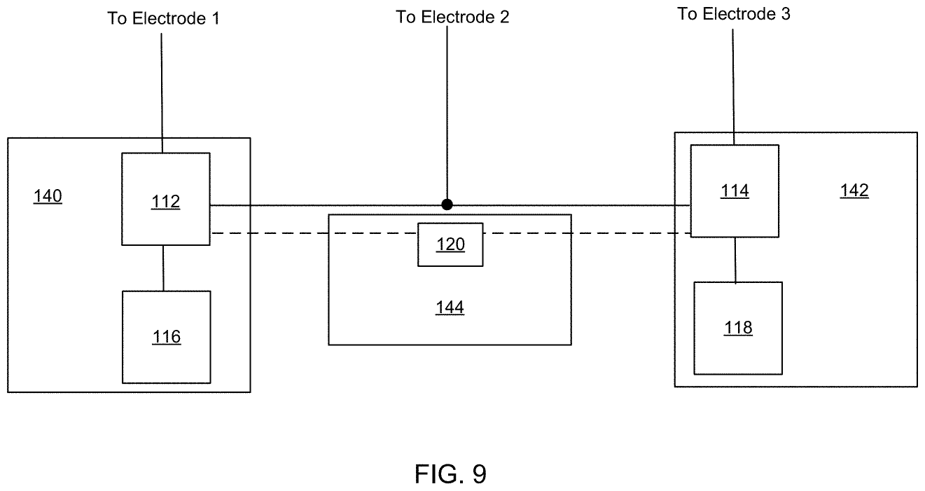

Referring next to FIG. 9, shown are exemplary aspects of the power sources 140, 142 and the controller 144. As shown, the power sources 140, 142 may receive direct power from a first direct current (DC) supply 116 and a second DC supply 118, respectively. In addition, the first power source 140 may include a first bi-polar controllable pulsed DC power supply 112, and the second power source 142 may include the second bi-polar controllable pulsed DC power supply 114.

Of note, each of the first and second power sources 140, 142 may be arranged and configured to be aware of the other one of the first and second power sources 140, 142, without attempting to control the operation of the other one of the first and second power sources 140, 142. Applicant has achieved this “awareness without control” by first configuring a frequency (e.g. 40 kHz) and duty of each of the first and second bi-polar controllable pulsed DC supplies 112, 114, and subsequently coupling the synchronizing unit 120 and configuring one of the first and second bi-polar controllable pulsed DC supplies 112, 114 to be perceived as a transmitter for the purpose of frequency synchronization, and the other one of the first and second bi-polar controllable pulsed DC supplies 112, 114 to be perceived as a receiver, for the purpose of frequency synchronization. In contrast, each one of the first and second DC supplies 116, 118 may be independent, and do not rely on awareness of the other one of the first and second DC supplies 116, 118 to properly function.

Although not required, in one implementation, the first and second DC supplies 116, 118 may each be realized by one or more ASCENT direct current power supplies sold by Advanced Energy Industries, Inc. of Fort Collins, Colo., U.S.A. And the first and second bi-polar controllable pulsed DC supplies 112, 114 may each be realized by an ASCENT DMS Dual-magnetron sputtering accessory, which is also sold by Advanced Energy Industries, Inc. of Fort Collins, Colo., U.S.A. In this implementation, the first and second power sources 140, 142 are each realized as an AMS/DMS stack wherein the ASCENT direct current power supply may provide straight DC power, and the DMS dual-magnetron sputtering accessory generates a pulsed DC waveform from the straight DC power and performs arc management. Beneficially, the DMS dual-magnetron sputtering accessories may be located in close proximity to the chamber 101, and the ASCENT direct current power supplies may be located remotely (e.g., in a remote rack) from the chamber 101. The synchronizing unit 120 in this implementation may be realized by a common exciter (CEX) function of the DMS accessories. In another embodiment, each of the first and second power sources 140, 142 may be realized by an integrated pulsed DC power supply.

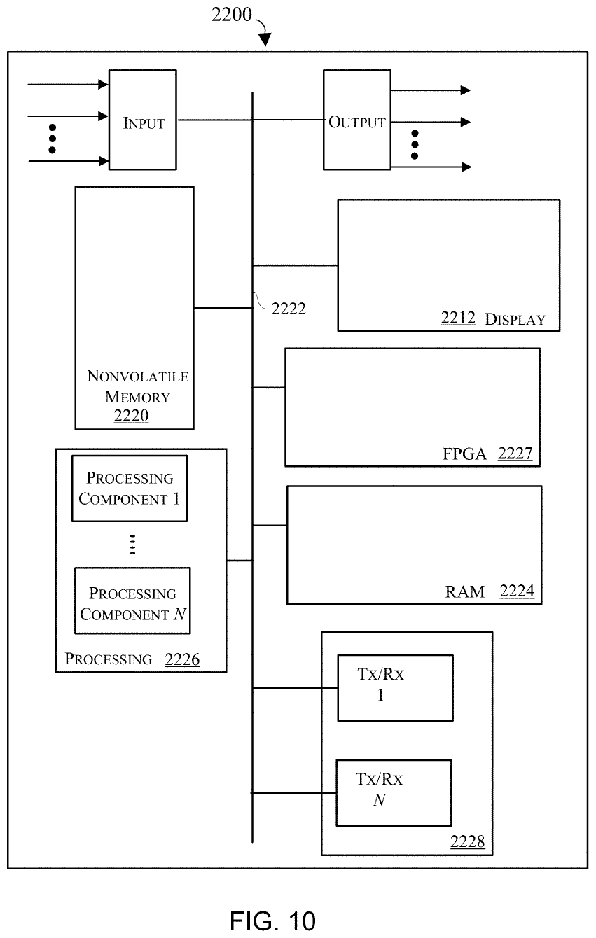

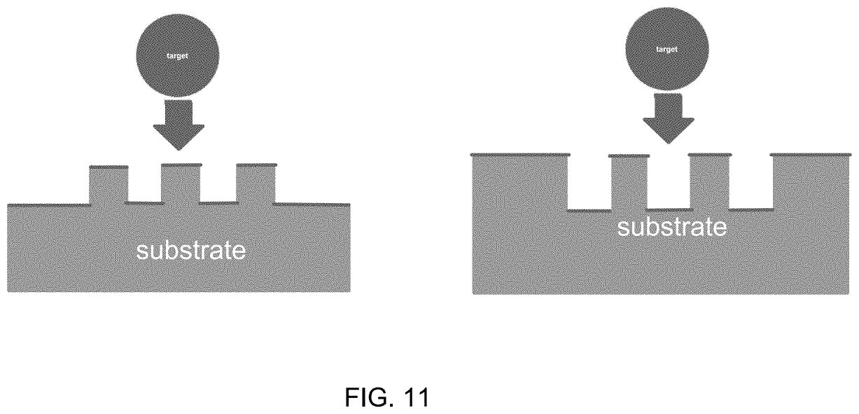

The methods (including the control methodologies) described in connection with the embodiments disclosed herein may be embodied directly in hardware, in processor executable instructions encoded in non-transitory processor readable medium, or in a combination of the two. Referring to FIG. 10 example, shown is a block diagram depicting physical components that may be utilized to realize the controller 144 according to an exemplary embodiment. As shown, in this embodiment a display 2212 and nonvolatile memory 2220 are coupled to a bus 2222 that is also coupled to random access memory (“RAM”) 2224, a processing portion (which includes N processing components) 2226, a field programmable gate array (FPGA) 2227, and a transceiver component 2228 that includes N transceivers. Although the components depicted in FIG. 10 represent physical components, FIG. 10 is not intended to be a detailed hardware diagram; thus, many of the components depicted in FIG. 22 may be realized by common constructs or distributed among additional physical components. Moreover, it is contemplated that other existing and yet-to-be developed physical components and architectures may be utilized to implement the functional components described with reference to FIG. 10.

This display 2212 generally operates to provide a user interface for a user, and in several implementations, the display 2212 is realized by a touchscreen display. In general, the nonvolatile memory 2220 is non-transitory memory that functions to store (e.g., persistently store) data and processor executable code (including executable code that is associated with effectuating the methods described herein). In some embodiments for example, the nonvolatile memory 2220 includes bootloader code, operating system code, file system code, and non-transitory processor-executable code to facilitate the execution of the methods described herein.

In many implementations, the nonvolatile memory 2220 is realized by flash memory (e.g., NAND or ONENAND memory), but it is contemplated that other memory types may be utilized. Although it may be possible to execute the code from the nonvolatile memory 2220, the executable code in the nonvolatile memory is typically loaded into RAM 2224 and executed by one or more of the N processing components in the processing portion 2226.

The N processing components in connection with RAM 2224 generally operate to execute the instructions stored in nonvolatile memory 2220 to enable the power sources 140, 142 to achieve one or more objectives. For example, non-transitory processor-executable instructions to effectuate the methods described herein may be persistently stored in nonvolatile memory 2220 and executed by the N processing components in connection with RAM 2224. As one of ordinary skill in the art will appreciate, the processing portion 2226 may include a video processor, digital signal processor (DSP), graphics processing unit (GPU), and other processing components.

In addition, or in the alternative, the FPGA 2227 may be configured to effectuate one or more aspects of the methodologies described herein. For example, non-transitory FPGA-configuration-instructions may be persistently stored in nonvolatile memory 2220 and accessed by the FPGA 2227 (e.g., during boot up) to configure the FPGA 2227 to effectuate the functions of the controller 144.

The input component may operate to receive signals that are indicative of one or more aspects of the power applied to the electrodes (e.g., magnetrons and/or the anodes). The signals received at the input component may include, for example, voltage, current, and/or power. The output component generally operates to provide one or more analog or digital signals to effectuate an operational aspect of the first and/or second power sources 140, 142. For example, the output portion may be a signal to cause the first bi-polar controllable pulsed DC power supply 112 and/or second controllable pulsed DC power supply 114 to effectuate some of the methodologies described herein. In some embodiments, the output component may operate to adjust a voltage, frequency, and/or duty of the first and/or second power source 140, 142.

The depicted transceiver component 2228 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

Referring briefly back to FIGS. 6, 7, and 8, the plasma chamber 101 may include a horizontal ground shield with an aperture positioned above the substrate 122, and the substrate 122 may rest on a movable platform that oscillates in any direction under the aperture to provide a more uniform thickness and more uniform material properties. These embodiments provide substantially better step coverage than prior art approaches.

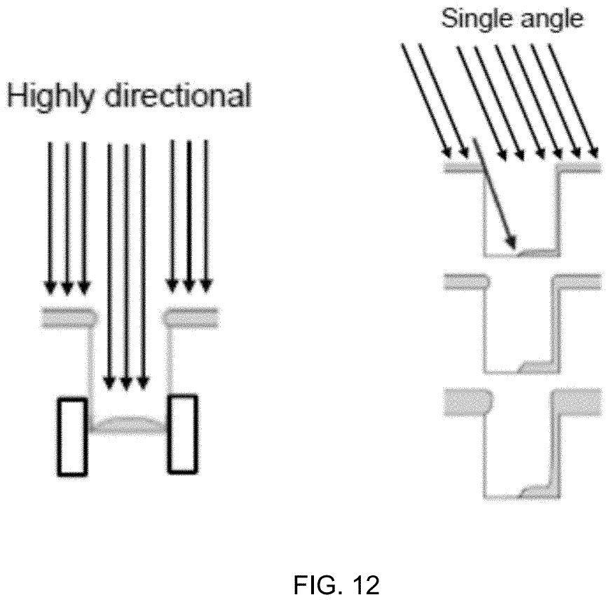

FIGS. 11 and 12, for example, depict the deficiencies that prior art approaches inherently include. FIG. 11 shows a single target in connection with a moving substrate, and FIG. 12 depicts the resultant directional and single angle results.

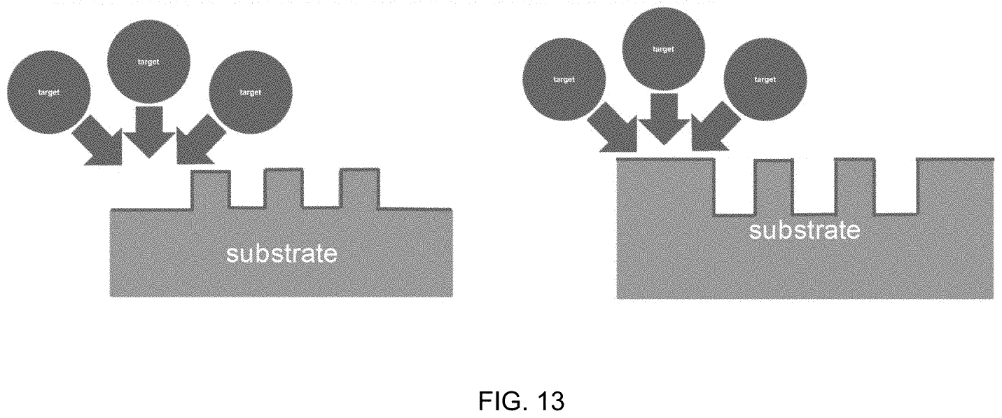

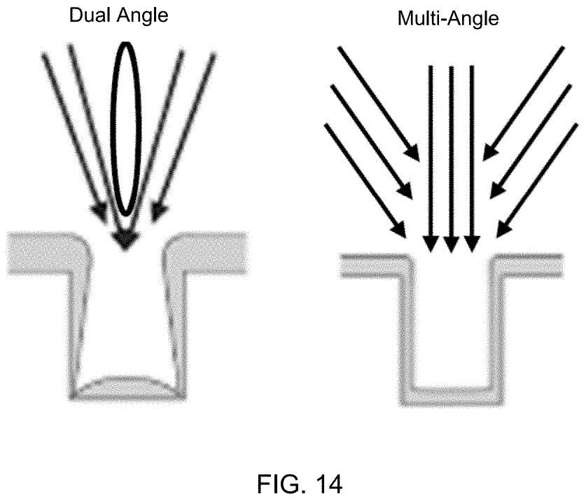

In contrast, FIG. 13 depicts multiple targets in connection with a moving substrate, and FIG. 14 depicts the dual angle coverage of two targets and the multi-angle coverage of three targets.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A pulsed sputtering system comprising:
first electrode, a second electrode, and a third electrode;
at least two, separate and different, target materials, each of the target materials coupled to a corresponding one of the electrodes;
a first power source coupled to the first electrode and the second electrode, wherein the first power source is configured to apply a first voltage at the first electrode that alternates between positive and negative relative to the second electrode during each of multiple cycles; and
a second power source coupled to the third electrode and the second electrode, the second power source is configured to apply a second voltage to the third electrode that alternates between positive and negative relative to the second electrode during each of the multiple cycles.

2. The pulsed sputtering system of claim 1, wherein the first electrode and the third electrode are each a part of a magnetron to form a first magnetron and a third magnetron wherein each of the first magnetron and the third magnetron is coupled to a corresponding one of the two separate and different target materials, and wherein the second electrode is neither coupled to a target nor a part of a magnetron to operate as an anode.

3. The pulsed sputtering system of claim 1, wherein each of the three electrodes is a part of a magnetron to form a first magnetron, a second magnetron, and a third magnetron, and wherein one of the at least two, separate and different, target materials is coupled to the first and third magnetron and another of the at least two, separate and different, target materials is coupled to the second magnetron.

4. The pulsed sputtering system of claim 1, wherein each of the three electrodes is a part of a magnetron to form a first magnetron, a second magnetron, and a third magnetron and the at least two, separate and different, target materials includes three separate and different target materials, wherein each of the three separate and different target materials is coupled to a corresponding one of the three magnetrons.

5. The pulsed sputtering system of claim 1, comprising a ground shield aperture and a movable platform to move a substrate in any direction to uniformly to deposit the at least two separate and different target materials on the substrate.

6. The pulsed sputtering system of claim 1, comprising a plasma chamber that encloses the first electrode, the second electrode, and the third electrode.

7. A method for sputtering comprising:
providing at least a first electrode, a second electrode, and a third electrode;
using each of at least two, separate and different, target materials in connection with one of the three electrodes;
applying a first voltage at the first electrode that alternates between positive and negative relative to the second electrode during each of multiple cycles; and
applying a second voltage to the third electrode that alternates between positive and negative relative to the second electrode during each of the multiple cycles.

8. The method of claim 7, comprising:
phase-synchronizing the first voltage with the second voltage, so both, the first voltage and the second voltage are simultaneously negative during a portion of each cycle and simultaneously positive relative to the second electrode during another portion of each cycle.

9. The method of claim 8, wherein:
the first electrode voltage and the third electrode voltage are simultaneously negative relative to the second electrode at least 70 percent of a time over the multiple cycles.

10. The method of claim 9, comprising:
applying a greater level of power during a half cycle when the first electrode voltage and the third electrode voltage are simultaneously positive relative to the second electrode.

11. The method of claim 10, comprising:
applying at least twice a level of power during a half cycle when the first electrode voltage and the third electrode voltage are simultaneously positive relative to the second electrode.

12. The method of claim 8, comprising:
applying a greater level of power during a half cycle when the first electrode voltage and the third electrode voltage are simultaneously negative relative to the second electrode.

13. The method of claim 7, comprising:
using each of at least three, separate and different, target materials in connection with the three electrodes.

14. The method of claim 7, comprising:
phase-desynchronizing the first voltage with the second voltage, so there is a phase offset between the first voltage and the second voltage.

15. The method of claim 7, comprising:
employing a horizontal ground shield aperture and moving a substrate in any direction to uniformly to deposit the at least two separate and different target materials on the substrate.

16. A pulsed sputtering system comprising:
a first electrode, a second electrode, and a third electrode;
at least two, separate and different, target materials, each of the target materials coupled to a corresponding one of the electrodes;
means for applying a first voltage at the first electrode that alternates between positive and negative relative to the second electrode during each of multiple cycles; and
means for applying a second voltage to the third electrode that alternates between positive and negative relative to the second electrode during each of the multiple cycles.

17. The pulsed sputtering system of claim 16 wherein each of the three electrodes is a part of a magnetron to form a first magnetron, a second magnetron, and a third magnetron, and wherein one of the at least two, separate and different, target materials is coupled to the first and third magnetron and another of the at least two, separate and different, target materials is coupled to the second magnetron.

18. The pulsed sputtering system of claim 16, wherein each of the three electrodes is a part of a magnetron to form a first magnetron, a second magnetron, and a third magnetron and the at least two, separate and different, target materials includes three separate and different target materials, wherein each of the three separate and different target materials is coupled to a corresponding one of the three magnetrons.

19. The pulsed sputtering system of claim 16, comprising a plasma chamber that encloses the first electrode, the second electrode, and the third electrode.

20. The pulsed sputtering system of claim 16, comprising phase-synchronizing the first voltage with the second voltage, so both, the first voltage and the second voltage are simultaneously negative during a portion of each cycle and simultaneously positive relative to the second electrode during another portion of each cycle.
